(19) United States
(12) Patent Application Publication
(10) Pub. No.: US 2009/0211901 A1
(43) Pub. Date: Aug. 27, 2009

(54) METHODS FOR PREPARING CNT FILM, CNT FILM WITH A SANDWICH STRUCTURE, AN ANODE INCLUDING THE CNT FILM AND AN ORGANIC LIGHT-EMITTING DIODES INCLUDING THE ANODE AND CNT DEVICE

(75) Inventors: Hisashi Kajiura, Tokyo (JP); Yongming Li, Tokyo (JP); Yu Wang, Beijing (CN); Yunqi Liu, Beijing (CN); Lingchao Cao, Beijing (CN); Dacheng Wei, Beijing (CN); Dachuan Shi, Beijing (CN); Hongliang Zhang, Beijing (CN); Gui Yu, Beijing (CN)

Correspondence Address: K&L Gates LLP, P. O. BOX 1135, CHICAGO, IL, 60690, US

(73) Assignee: SONY CORPORATION, Tokyo (JP)

(21) Appl. No.: 12/370,176

(22) Filed: Feb. 12, 2009

(30) Foreign Application Priority Data
Feb. 14, 2008 (CN) 200810005631.7

(51) Int. Cl. C25B 11/04; B05D 3/02; B32B 37/00; B32B 23/20; B32B 9/04; B28B 1/14; B82B 1/00

(52) U.S. Cl. 204/290.15; 427/372.2; 156/230; 428/480; 428/408; 264/299; 977/750

(57) ABSTRACT

Methods for preparing flexible transparent conducting carbon nanotube (CNT) films, the CNT film prepared from said methods, a method of treating CNT film by using thionyl bromide (SOBr₂) as a dopant are provided. A novel CNT film laminate with a sandwich structure are also provided, a transparent, flexible anode including the CNT film and an organic light-emitting diodes (LEDs) including the anode are also provided. The method of the present application can very quickly and completely remove the filter membrane, compared with a general immersion method. CNTs are not destroyed by the “soft method”, which will allow for expanded applications in electroluminescent or photovoltaic devices.

### CROSS REFERENCES TO RELATED APPLICATIONS

The present application claims priority to Chinese Patent Application No. CN 200810005631.7 filed in the Chinese Patent Office on Feb. 14, 2008, the entire contents of which is being incorporated herein by reference.

### BACKGROUND

As one-dimensional nanomaterials, carbon nanotubes (CNTs) have increasingly become the focus of intense multidisciplinary study and present many new opportunities for fundamental science and new technologies, due to their unique physical and chemical properties and their prospects for practical applications. CNTs combine strength and flexibility, and thus are excellent candidates for flexible electronic components. Recently, flexible, transparent, conducting thin films made of CNTs have attracted much attention and been a subject of current interest, partly due to applications in electroluminescent, photoconductor and photovoltaic devices.

Although the optically transparent and highly conductive indium tin oxide (ITO) has enjoyed widespread use in optoelectronic applications, the inherent brittleness of ITO severely limits film flexibility. The properties of CNT thin films make them suitable replacements for ITO. For instance, CNT films can be repeatedly bent without fracture. The thin films with low sheet resistance are also transparent in the visible and infrared range. Furthermore, both the low cost and tunable electronic properties offer additional advantages for CNT thin films.

Pure CNTs obtained from the various preparation methods are well known for poor solubility and low dispersability in aqueous and organic liquids, which leads to difficulties in their manipulation and incorporation into different matrixes. Aggregation is particularly problematic because the highly polarizable, smooth-sided nanotubes readily form parallel bundles or ropes with a van der Waals binding energy of ˜500 eV per micrometer of tube-tube contact, see for example, Moore, V. C. et al., Nano Lett. 2003, 3, 1379. This bundling perturbs the electronic structure of the CNTs, and makes homogeneous chemical reactions impossible. The resulting CNT-based films will exhibit a strength, modulus and conductivity much lower than expected (see, for example Baughman, R. H. et al., Science 2002, 297, 787).

On the other hand, although it has been shown in Yurekli, K. et al., J. Am. Chem. Soc. 2004, 126, 9902, that some surfactants can result in the stable dispersions by structureless random adsorption on the CNTs, they do cover up or denature the CNTs (see O'Connell, M. J. et al., Chem. Phys. Lett. 2001, 342, 265. Matarredona, O. et al., J. Phys. Chem. B 2003, 107, 13357. Moore, V. C. et al., Nano Lett. 2003, 3, 1379).

Recently, Geng, H. Z. et al. (Geng, H. Z. et al., J. Am. Chem. Soc. 2007, 129, 7758) proposed that acid treatment is efficient for the removal of surfactants. However, Hu, H. et al. (Hu, H. et al., J. Phys. Chem. B 2003, 107, 13838), Zhang, M. et al. (Zhang, M. Et al., J. Phys. Chem. B 2004, 108, 149), and Ziegler, K. J. et al. (Ziegler, K. J. et al., J. Am. Chem. Soc. 2005, 127, 1541) indicate that most CNTs have been reported to be destroyed during acid treatment, which will have a great impact on the properties of the devices based on these CNT films.

Furthermore, although the process of preparing CNT film based on the filtration method is a simple and easy process, the step for the removal of the filter membrane requires a great deal of time and “cleaning agent” (e.g. acetone) during immersion. If the filter membrane can not be entirely removed, it will increase the sheet resistance of CNT films and reduce their transmittance. As a consequence, after the CNTs are dispersed and then fabricated into films, it is essential to find a method to remove the surfactants and filtration without damaging the CNTs.

### SUMMARY

The present application relates to carbon nanotube (CNT) film preparing methods, specifically to preparing methods of flexible transparent conducting carbon nanotube (CNT) films and the CNT films prepared therefrom according to an embodiment. The methods of present application can improve the conductivity of the resulting flexible transparent conducting carbon nanotube films. The present application in an embodiment also relates to a method of treating CNT films by using thionyl bromide (SOBr₂) as a dopant, a novel CNT film laminate with a sandwich structure, a transparent, flexible anode including the CNT film and CNT devices including the anode, such as LEDs.

In a first embodiment, there is provided a method of preparing flexible transparent conducting carbon nanotube films, which includes:

dispersing a CNT in a surfactant to form a dispersion;

filtering out the dispersion with a filter membrane and forming a CNT film on the filter membrane;

removing substantially all of the surfactant on an obverse side (e.g., a side not in contact with the filter membrane as illustrated in FIG. 1(a)) of the CNT film by a buffer.

In an embodiment, the filter membrane is removed by using a vapor.

In an embodiment, the surfactant is removed on a reverse side of CNT film (e.g., a side opposite the obverse side as further illustrated in FIG. 1(a)).

In an embodiment, the CNT film is washed and transferred onto a substrate prior to remove the filter membrane and/or surfactant.

In an embodiment, the buffer is Tris(hydroxymethyl)aminomethane hydrochloride (Tris-HCl).

In an embodiment, the filter membrane is a mixed cellulose ester (MCE) filter membrane.

In an embodiment, the surfactant is octyl-phenol-ethoxylate.

In an embodiment, the substrate is quartz substrate.

In an embodiment, the CNT film is immersed in an aqueous methanol solution to remove the surfactant on the reverse side of CNT film.

In an embodiment, the vapor is acetone vapor.

In an embodiment, the CNT is single-wall carbon nanotube (SWNT).

In a second embodiment, there is provided a method of preparing a flexible transparent conducting carbon nanotube (CNT) films, which includes:

dispersing a CNT in a surfactant to form a dispersion;

filtering out the dispersion with a filter membrane and forming a CNT film on the filter membrane;

removing the surfactant on an obverse side and a reverse side of the CNT film.

In an embodiment, substantially all of the surfactant is removed on the obverse side of the CNT film by a buffer.

In an embodiment, the buffer is Tris(hydroxymethyl)aminomethane hydrochloride (Tris-HCl) buffer.

In an embodiment, the CNT film is immersed in an aqueous methanol solution to remove the surfactant on the reverse side of CNT film.

In an embodiment, the film is transferred onto a substrate after removing the surfactants on the obverse side and before removing the surfactants on the reverse side of the film.

In an embodiment, the CNT is SWNT.

In a third embodiment, there is provided a preparing method of flexible transparent conducting carbon nanotube (CNT) films, which includes:

dispersing a CNT in a surfactant to form a dispersion;

filtering out the dispersion with a filter membrane and forming a CNT film on the filter membrane;

removing the filter membrane by using a vapor.

In an embodiment, the vapor is acetone vapor.

In an embodiment, the CNT is SWNT.

In a fourth embodiment, there is provided a CNT film prepared by a method according to any one of the first to third embodiments.

In a fifth embodiment, there is provided a method of treating a CNT film with thionyl bromide (SOBr₂) used as a dopant.

In an embodiment, the CNT is SWNT.

In a sixth embodiment, there is provided a CNT film laminate with a sandwich structure, which includes multiple layers of a CNT film, such as four layers of the CNT film.

In an embodiment, each layer of the CNT film laminate is treated with thionyl bromide.

In an embodiment, CNT is SWNT.

In a seventh embodiment, there is provided a transparent, flexible anode including the CNT film laminate with a sandwich structure including a plurality of layers of a CNT film.

In an eighth embodiment, there is provided an organic light-emitting diode (LED) including the anode according to the seventh embodiment.

In a ninth embodiment, there is provided a CNT device including a CNT film including laminate thereof obtained from any one method according to the first to sixth embodiments.

In an embodiment, CNT is a single-wall carbon nanotube (SWNT), such as a thin single-wall carbon nanotube.

Additional features and advantages are described herein, and will be apparent from the following Detailed Description and the figures.

### BRIEF DESCRIPTION OF THE FIGURES

FIG. 1A is a schematic illustration of the preparing method for a CNT film according to the first embodiment;

FIG. 1B is a typical setup for the removal of the filter membrane in the first and third embodiments, in which a vapor generator which may be used in the method of the first and third embodiments is depicted;

FIG. 1C is a schematic cross-section view of glass casing of vapor generator shown in FIG. 1B.

FIG. 2 shows comparative sheet resistance-transparency curves of the CNT films prepared according to the prior art preparing method (reported in Wu, Z. C. et al. Science 2004, 305, 1273, which is referred to “the prior art preparing method” hereafter) and the preparing method according to an embodiment of the present application. In the region within the circle, all of the sheet resistance-transparency curves of the CNT films tend to come together, showing that their sheet resistances do not depend on the type of CNTs or the purity of films, but rather on the continuity among the carbon nanotubes.

FIG. 3 shows SEM images of CNT films of: (a) 98.8% transparency H-CNT film, (b) 95.3% transparency P-CNT film, (c) 95.9% transparency L-CNT film, and (d) 91% transparency L-CNT film.

FIG. 4 shows the resistance percent of essential CNT film in the unpurified film. The inset shows the components that compose the whole resistance of the CNT film with 78% transparency.

FIG. 5 shows FT-IR spectra of the CNT films according to the prior art preparing method and the preparing method according to an embodiment of the present application.

FIG. 6A is an SEM image of the four-layer sandwich structure according to an embodiment. The inset is a high-magnification view of the multilayer structure;

FIG. 6B is a schematic diagram of the sandwich structure according to an embodiment, in which each layer is processed according to the fifth embodiment.

FIG. 7 shows transparency spectra for the four-layer CNT film laminate, showing the transparency value for each layer. The transparency of the CNT films decreases monotonically with an increase in the number of layers.

FIG. 8 shows Raman spectra of CNT films before and after SOBr₂ treatment.

FIG. 9 shows XPS core level spectra of L-CNT films treated with SOBr₂: (a) C1s, (b) O 1s (c) S 2p (d) Br 3d.

FIG. 10 shows SEM images of L-CNT films: (a) pristine L-CNT film. (b) SOBr₂ treatment. The chemical modification results in the link between the nanotubes and forms much larger bundles.

### DETAILED DESCRIPTION

The present application is described below in further detail with reference to the figures according to an embodiment.

### The First Embodiment

According to the first embodiment, a preparing method of flexible transparent conducting carbon nanotube films is provided, which includes dispersing a CNT in a surfactant to form a dispersion; filtering out the dispersion with a filter membrane and forming a CNT film on the filter membrane; removing substantially all of the surfactants on the obverse side of the CNT film by a buffer.

The CNT, surfactants, filter membranes and substrates are those commonly used in the art.

For example, the CNT includes Laser nanotubes, arc-discharge nanotubes (P-CNTs), HiPCO nanotubes (H-CNTs) and the like. The latter two kinds of CNT are commercially available, such as from Carbon Solutions Inc. as P3 nanotubes and Carbon Nanotechnology Inc., respectively. Regarding the Laser nanotubes, these types of CNT are described, for example, in Guo, T. et al., Chem. Phys. Lett. 1995, 243, 49; and Thess, A. et al., Science 1996, 273, 483.

In an embodiment, the CNT films are fabricated with a procedure based on a filtration method, such as the method reported in Wu, Z. C. et al., Science 2004, 305, 1273. However, the present application is not limited to this method and can include other suitable and conventional methods, such as forming CNT films by drying, by LB deposition, by air brushing, and by PDMS transfer printing.

The surfactants used in the present application are those commonly used to treat CNT. Some illustrative, non-limiting examples of suitable surfactants include: trioctyl amine (TOA), cellulose ether, sodium dodecyl benzene sulfonate, Triton X-100, sodium diisooctyl succinate sulfonate, hexadecyl trimethyl ammonium chloride and octadecyl trimethyl ammonium chloride and the like.

Among these surfactants, in view of ease of availability and the cost, Triton X-100 and sodium dodecyl benzene sulfonate are preferably used.

The present application is not limited to the type of filter membranes used in the method of the first embodiment, provided that the filter membranes can filter out the surfactants in the CNT dispersion. For example, suitable filter membranes include mixed cellulose ester (MCE) filter membrane, such as, Millipore, 0.2 μm pore.

The substrates used in the method of the first embodiment are those commonly used in the art, provided that the substrates can support the CNT film. Suitable substrates include, for example, quartz substrate, glass sheet, silica sheet and polyethylene terephthalate (PET).

In an embodiment, a buffer is used to remove the surfactants. The benefits of the use of the buffers are that: no damage occurs to the CNT, it is easy to be removed, and the removal of the remaining surfactant (such as Triton X-100) is effective.

The examples of the buffer suitable for the method of the first embodiment are, for example, tris(hydroxymethyl)aminomethane hydrochloride (Tris-HCl) buffer.

The pH of the buffer is generally 7 to 8 according to an embodiment.

For example, a Tris(hydroxymethyl)aminomethane hydrochloride (Tris-HCl) buffer with a pH of 7.5 is used as the buffer of the method.

The type of vapor used in the method of the first embodiment, depends mostly on the filter membrane used. For example, in the case that a mixed cellulose ester film filter is used, the vapor includes the vapor of acetone, methanol, DMF, pyridine and tetrahydrofuran and the like.

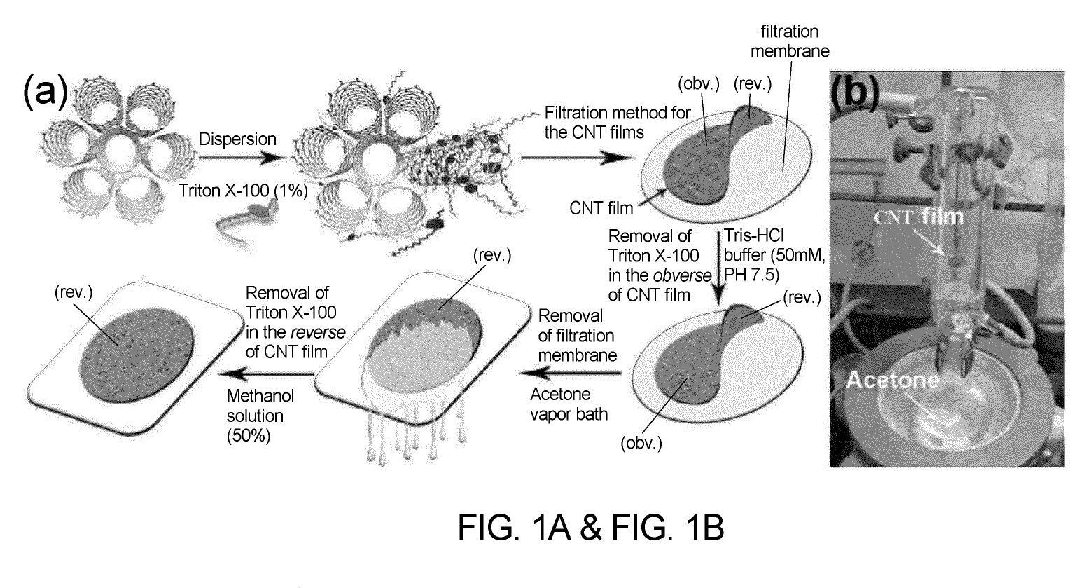

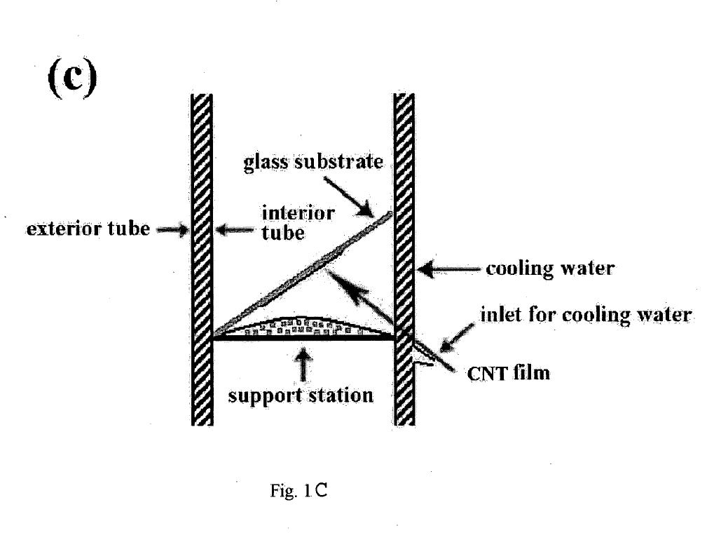

It should be understood that any suitable method to generate the vapor and the method to remove the filter membrane by using a vapor can be used. For example, the vapor generator shown in FIG. 1B can be used to remove the filter membrane according to an embodiment.

Hereafter, the vapor generator used in the examples is explained. As indicated in FIG. 1B, the generator includes:

a glass casing with a condensing device, having a porous support station in the inner of the casing for disposing a sample, an inlet of a condensing media located on the lower portion of the casing and an outlet of the condensing media located on the upper portion of the casing, and the height of the station is nearly the same as that of the inlet of the condensing media;

a vessel, such as round-bottomed flask, to hold solvent, such as acetone;

a heating device, such as temperature-adjustable heating jacket, to heat the solvent; and

an optional mixing device, such as magnetic stirrer.

The porous support station is made of, for example, glass. There is no restriction on the pore size of said station, provided that enough amount of vapors can go through the station and a sample can be supported by the station. The size of the station is determined by the inner diameter of the glass casing.

The process for fabricating the glass casing is described in detail as follows.

First, a porous support station is sintered into the inner portion of a glass tube having a relatively small diameter (such as, φ=30 mm, h=20 cm). Then, the glass tube is sintered into the inner of a glass tube with a relatively large diameter (such as, (φ=50 mm, h=20 cm), followed by forming the inlet and outlet for condensing media (e.g. water) on the lower and upper portion of the glass tube with the relatively large diameter, respectively. Finally, a ground interface is welded on an end of the casing. Therefore, a glass casing is accomplished. The glass tube with the relatively small diameter (inner tube) and the glass tube with the relatively large diameter (outer tube) do not have fluid communication therebetween. The condensing media flows between said two tubes. That is, the media flows outside of the inner tube and inside of the outer tube. As indicated above, one end of the inner tube and one end of the outer tube are connected by the ground interface, while the other end of the inner tube may be connected to a solvent recovering device (not shown). Otherwise, the other end of the inner tube may be open. In this case, the length of casing tube should be enough in order to reflux the entire solvent vapor back to the vessel.

FIG. 1C provides a schematic cross-sectional view of glass casing of vapor generator shown in FIG. 1B.

The vapor generator is achieved by for example, assembling the glass casing, the vessel and the heating device from top to bottom. The mixing device is suitably positioned depending on the type of the mixing device.

The mixing by the mixing device may be continued during the use of the generator, in order to avoid over-boiling.

Water may be used in the generator as the condensing media.

### The Procedure of the Method of the First Embodiment

The CNTs are first dispersed in the surfactants with mixing if desired. There is no restriction on the process and the duration for the dispersing. The CNTs can be dispersed in a suitable surfactant with a suitable process within an appropriate time until a homogeneous dispersion is obtained. The dispersing time can be any suitable time. For example, the dispersing time can range from 10 minutes to 3 hours, preferably 20 minutes to 1 hour.

After the dispersion is obtained, it is filtered out by a filter membrane and CNT films are achieved. This step can be carried out in a vacuum filtration apparatus in order to prevent any impurities from carrying into the films.

Then, the resulting CNT film on the filter membrane is dialyzed against a buffer. The dialyzing time depends on the buffer used, and the treatment may proceed until substantially all the surfactants on the obverse side of the CNT film are removed. The treatment time can include any suitable amount of time. For example, the treatment time can be 6 hours to 7 days, preferably 48 hours to 3 days, such as 2.5 days.

According to an embodiment, the buffer can be removed by washing, for example, with a suitable solvent, such as purified water after dialyzing. Subsequently, the CNT film is optionally transferred onto a substrate. The film is dried at a suitable temperature over a suitable time. For example, the film on the substrate can be dried for 0.5 to 1.5 hour at about 80° C. to 100° C.

The filter membrane is then removed by a suitable method. The membrane can be removed by immersing itself in the cleaning agent, such as acetone, according to conventional procedures. However, according to an embodiment, the filter membrane is removed by using a vapor, see, for example, as shown in FIG. 1B. The treatment time for this step is generally 60 minutes to 2 hours. As a result, the CNT film is left on the substrate when a substrate is used.

Thereafter, the film may be immersed in a suitable solvent to remove the surfactants on the reverse side of the film. Examples of the suitable solvent include, but are not limited to, an aqueous methanol solution, ethanol solution and the like.

Finally, the CNT film is dried under a vacuum. Conventional conditions for the drying, such as degree of vacuum, drying temperature and time and the like, can be used. In an embodiment, the degree of the vacuum is 0.01 MPa.; the temperature can vary from 50 to 200° C.; and the time may vary from 0.5 to 2 hours.

The method of the present application can improve the conductivity of the resulting flexible transparent conducting carbon nanotube (CNT) films. With a vapor, the filter membrane can be removed quickly and effectively. Further, the preparing method of the present application can remove the residual Triton X-100 surfactants. The results shown in the Example Part indicate that the sheet resistances of the CNT films drop relative to the preparing method of the present application.

### The Second Embodiment

According to the second embodiment, a preparing method of flexible transparent conducting carbon nanotube (CNT) films includes dispersing the CNT in a surfactant to form a dispersion; filtering out the dispersion with a filter membrane and forming a CNT film on the filter membrane; and removing the surfactant on the obverse side and the reverse side of the CNT film.

In order to remove the surfactants on the reverse side of the CNT film, the CNT film is immersed in an aqueous methanol solution according to an embodiment.

In order to remove the surfactants on the reverse side of the CNT film, the film is transferred onto a substrate after removing the surfactants on the obverse side of the film according to an embodiment.

Optionally, the filter membranes are removed after removing the surfactants on the obverse side of the CNT film and before transferring the film onto a substrate according to an embodiment.

The removal of the membranes can be achieved by any suitable method, as indicated above, but preferably by using a vapor.

The components used in the method of the second embodiment, such as CNT, surfactants, filter membrane, buffer, vapor and the substrates are same as those mentioned in the first embodiment as described above.

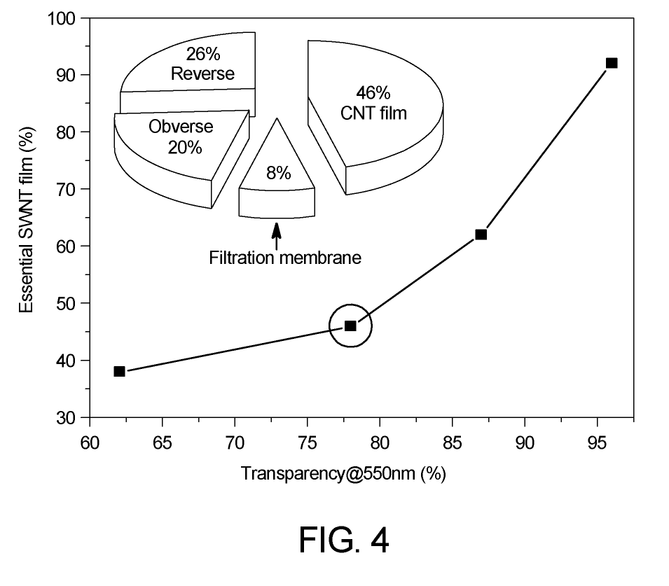

The method of the present application can remove the surfactants on both sides of the CNT film. Therefore, improvement on the conductivity of CNT films is achieved. It can be seen from FIG. 4, when the resistance after the removal of the filter membrane and surfactants according to the prior method is taken as a basis (total resistance), the resistance generated from the surfactants on the reverse side of the CNT film amounts 26% of the total resistance, and the resistance generated from the surfactants on the obverse side of the CNT film amounts to 20% of the total resistance. It is apparent that the further removal of the surfactants on the reverse side of the CNT film after the removal of the surfactants on the obverse side of the CNT film will substantially improve the conductivity of the CNT films, such as flexible transparent conducting carbon nanotube (CNT) films.

### The Third Embodiment

According to the third embodiment, a preparing method of flexible transparent conducting carbon nanotube (CNT) films includes dispersing the CNT in a surfactant to form a dispersion; filtering out the dispersion with a filter membrane and forming a CNT film on the filter membrane; and removing the filter membrane by using a vapor.

In the method of the third embodiment, the surfactants on the CNTs may be optionally removed by any suitable method.

The components used in the method of the third embodiment, such as CNT, surfactants, filter membrane and the vapor are the same as those mentioned in the first embodiment.

The method of the present application can improve the conductivity of resulting flexible transparent conducting carbon nanotube (CNT) films.

### The Fourth Embodiment

According to the fourth embodiment, CNT films obtained by any one of the methods in the first to third embodiments are provided.

During the removal of surfactants and the filter membrane according to the first to third embodiments, the filter membrane can be removed much more quickly and completely compared with the immersion method.

Specifically, since the use of the vapor can very quickly and completely remove the filter membrane, compared with a conventional immersion method, the resulting CNTs from the method of the first and third embodiments are not destroyed by the “soft method”, which will allow for expanded applications in electroluminescent or photovoltaic devices.

Furthermore, the CNT films obtained by the second embodiment (e.g. by removing the surfactants on the reverse side and obverse side of the CNT films) display enhanced properties.

### The Fifth Embodiment

According to the fifth embodiment, there is provided a method of treating a CNT film, wherein thionyl bromide (SOBr₂) is used as a dopant.

The CNT films may be prepared by any suitable method from any suitable CNT. Preferably, the CNT films are prepared by the method according to the first to third embodiments as previously discussed.

After a CNT film is formed, the film is immersed into SOBr₂ for a period of time, such as 3 to 12 hours, depending on the thickness of the film, according to an embodiment.

More detailed information is provided in the Examples described later in the present application.

### The Sixth Embodiment

To further increase conductivity of the films, a CNT film laminate with a multiple-layered sandwich structure is fabricated in combination with the chemical modification according to an embodiment.

In an embodiment, each layer of the CNT film laminate is modified by using thionyl bromide (SOBr₂) as a dopant.

In an embodiment, the CNT film laminate has a four layer structure.

According to an embodiment, the CNT films are prepared with the method of any one of the first to third embodiments. Then, a first CNT film is treated by the method of the fifth embodiment. Then, a second CNT film is stacked on the treated first CNT film. After a treatment according to the method of the fifth embodiment, a third CNT film is stacked on the stack of the first and second films. Thereafter, a fourth CNT film is stacked and treated after a treatment to the third film. Finally, a CNT film laminate with a sandwich structure is achieved.

### The Seventh Embodiment

The CNT film laminate with a sandwich structure can be applied as transparent, flexible anodes for organic light-emitting diodes (LEDs). An improvement in the properties of devices implies that the CNT films have promising applications in optoelectronics.

According to seventh embodiment, a transparent, flexible anode including the CNT film laminate of seventh embodiment is provided.

### The Eighth Embodiment

According to the eighth embodiment, an organic light-emitting diode (LEDs) including the anode of the seventh embodiment is provided.

### The Ninth Embodiment

According to the ninth embodiment, a CNT device is provided that includes a CNT film obtained from any method according to the first to sixth embodiments.

More specifically, the CNT devices include CNT conductive film, field emission source, transistor, conductive wire, spin conduction device, nano-electro-mechanic system (NMES), nano cantilever, quantum computing device, lighting emitting diode, solar cell, surface-conduction electron-emitter display, filter, drug delivery system, space elevator, thermal conductive material, nano nozzle, energy storage system, fuel cell, sensor, and catalyst support material.

CNT is preferably SWNT in an embodiment.

### EXAMPLES

The following substances are used in the examples.

Tri(hydroxymethyl)aminomethane: Acros, 99%;

HCl: Beijing Chemical, content of HCl is 36-38%;

Methanol: Beijing Chemical, 99.5%;

Acetone: Beijing Chemical, 99.5%;

Triton X-100: Acros;

SOCl₂: Acros, 99.7%;

SOBr₂: Alfa Aesar, 97%.

### Example 1

The transparent conductive thin films were made with three types of CNTs for comparative studies:

Laser nanotubes (L-CNTs)(see, (1) Guo, T. et al., Chem. Phys. Lett. 1995, 243, 49. (2) Thess, A. et al., Science 1996, 273, 483.),

Arc-discharge nanotubes (P-CNTs, P3 nanotubes from Carbon Solutions Inc.) and

HiPCO nanotubes (H-CNTs, Carbon Nanotechnology Inc.).

The CNT films were respectively fabricated using a procedure based on the filtration method reported by Wu et al. (see, Wu, Z. C. et al., Science 2004, 305, 1273).

The Tris(hydroxymethyl)aminomethane hydrochloride (Tris-HCl) buffer is prepared in a conventional manner. For example, the production of Tris(hydroxymethyl)aminomethane hydrochloride (Tris-HCl) buffer (50 mM, pH 7.5) is described as follows: 3.0 g of Tris was dissolved into 250 ml of deionized water; the result was poured into 500 ml of volumetric flask; the pH was adjusted to 7.5 with a IM of HCl; and the total volume of the solution was made to 500 ml with deionized water. Then, a 50 mM buffer was thus obtained.

The schematic diagram of the process for this example is shown in FIG. 1A.

Typically, 10 mg of CNTs were dispersed in 200 ml of 1 wt. % aqueous octyl-phenol-ethoxylate (denoted Triton X-100) solution for 20 min in an ultrasonic bath. The dispersion was filtered out with a mixed cellulose ester (MCE) filter membrane (Millipore, 0.2 μm pore), and the resulting CNT film was formed on the membrane in a vacuum filtration apparatus (Millipore). Substantially all of the Triton X-100 on one side of the CNT film was dialyzed against a Tris(hydroxymethyl)aminomethane hydrochloride (Tris-HCl) buffer (50 mM, PH 7.5) for two days. The Tric-HCl buffer was subsequently washed away with purified water, following which the CNT films were transferred onto a quartz substrate. After drying the sample for 1 h at 90° C., the filter membrane was removed by using acetone vapor (see, e.g. FIG. 1B), leaving CNT thin film on the substrate. The CNT film was then immersed in 50% aqueous methanol solution in order to remove the Triton X-100 on the reverse side of CNT film. Finally, the CNT films were dried in a vacuum at 100° C. for 1 h.

### Analyzing Method

The as-produced CNT films were examined by scanning electron microscopy (SEM, Hitachi S-4300F). For Fourier transfer infrared (FT-IR) spectroscopic analysis, the sample was ground and the fine powder sample was mixed with dry potassium bromide. The mixture was then made into a film that was analyzed in the beam of the FT-IR spectrophotometer (Bruker TENSOR 27). The transparency measurements of the CNT films were obtained using a UV/vis/NIR spectrophotometer (JASCO V-570). Raman spectra were recorded on a Renishaw 1000 micro-Raman system with a CCD detector. A He—Ne laser with an excitation energy of 1.96 eV (633 nm) served as the excitation source, and the spot size was 1 μm in diameter. X-ray photoelectron spectroscopy (XPS) data was obtained with an ESCALab220i-XL electron spectrometer from VG Scientific using 300 W AlKα radiation. The base pressure was about 3×10⁻⁹ mbar. The binding energies were referenced to the C1s line at 284.8 eV from adventitious carbon. For analysis, appropriate smoothing for the raw data and background removal using the Shirley method (see, Briggs, D. et al., Practical Surface Analysis, 2nd ed, Vol. 1, Auger and X-Ray Photoelectron Spectroscopy, Wiley, New York, 1990) was applied. The sheet resistances of the CNT film were measured in a low-resistivity meter with a 4-pin probe (Loresta-EP MCP-T360). The transparency of the carbon nanotube films is measured with UV-vis-NIR spectrophotometer (JASCO V-570).

### Results and Discussion

As far as the CNTs themselves are concerned, many factors have an effect on their electronic properties, including diameter, chirality, defect, curvature, local environment and so on. Although significant challenges remain, efforts were made to explore the chiral controlling growth of perfect CNTs. The inhomogeneous distribution of CNT constituents with respect to length, diameter and chirality further complicates the electronic properties of the films. Therefore, for CNT films, their resistances will result from three distinct parts. One is from the CNTs themselves. Another is from the lack of alignment and existence of the Schottky barrier at the intertube junctions (see, Fuhrer, M. S. et al., Science 2000, 288, 494.).

The third is from the additional resistance introduced during the fabrication process of the CNT films. This fabrication process, based on the filtration method reported by Wu et al, (see, Wu, Z. et al, Science 2004, 305, 1273) is quite simple. Another advantage is that the homogeneity and thickness of the films are readily controlled. However, the remnants of the surfactants and filter membrane will increase the sheet resistance of the CNT films and reduce their transmittance.

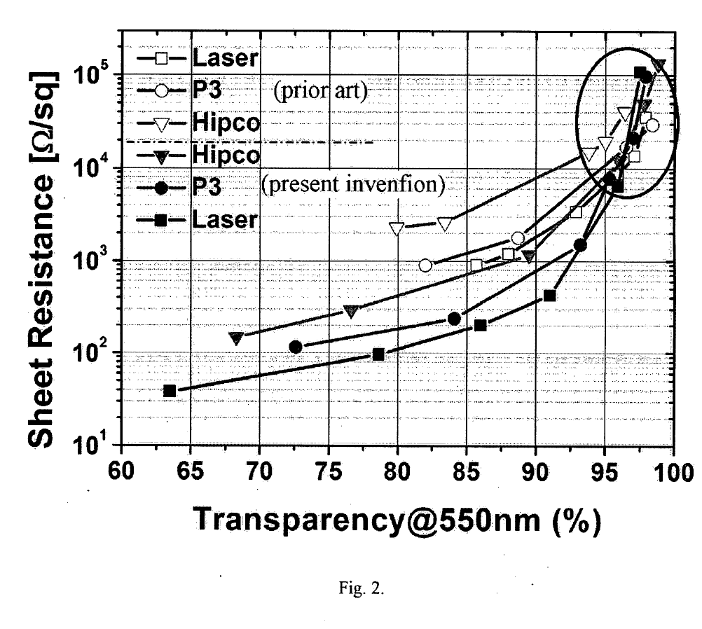

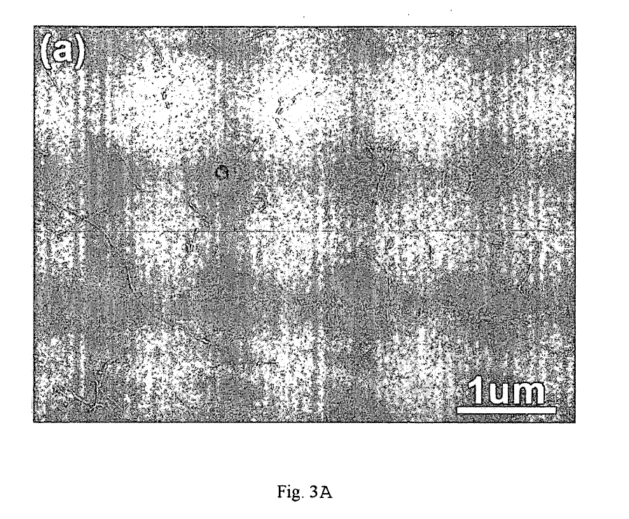

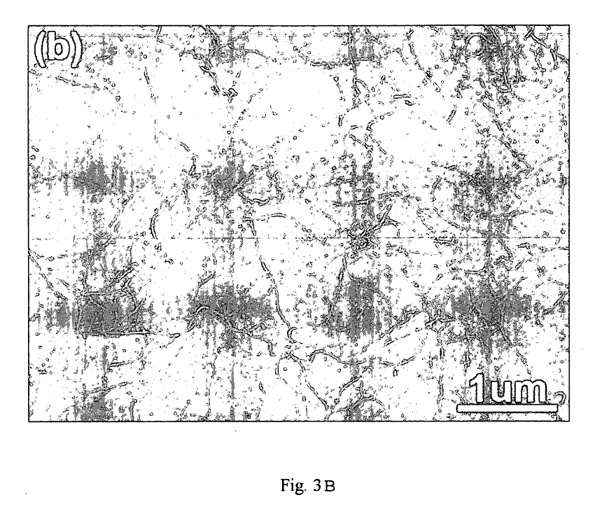

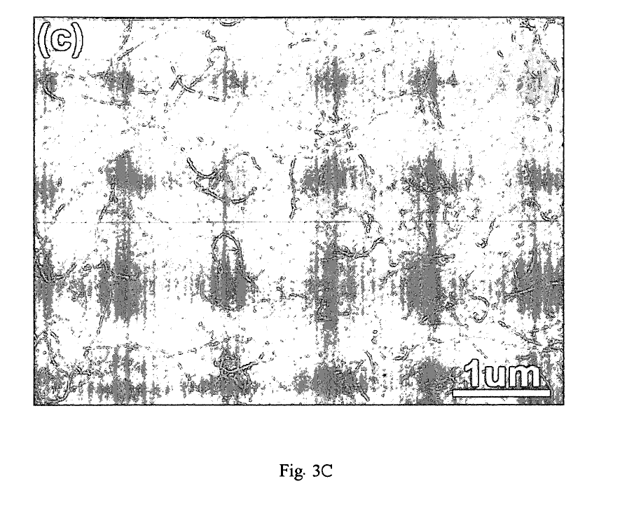

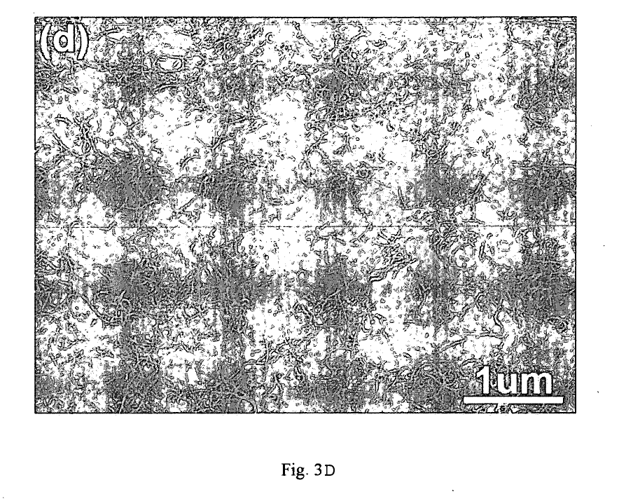

The transparency of the films at 550 nm versus the sheet resistance is plotted in FIG. 2. It can be seen that all of the sheet resistances of the films according to the preparing method of the present application have varying degrees of improvement. The L-CNT films take on the lowest sheet resistances while the sheet resistances of the H-CNT films are the highest. The resistances of the P-CNT films are close to those of the L-CNT films. In principle, the resistances of the P-CNT films and L-CNT films should be similar because of the same range of diameter and length. In this case, the relative inferior purity of the P-CNT samples is responsible for the higher resistances, even though they have been purified. The highest resistances of the H-CNT films depend on their much smaller diameter and length compared to those of the L-CNTs or P-CNTs. This is in accordance with the theoretical prediction that very weak back-scattering in large diameter tubes will lead to an increase in conductance. (see, (a) Kaun, C. C. et al., Phys. Rev. B 2002, 65, 205416; and (b) Lammert, P. E. et al., Phys. Rev. Lett. 2001, 87, 136402). It is noticeable that there is an obvious characteristic in the region within the circle of FIG. 2. When transparency rises above 95%, all of the resistance-transparency curves tend to come together. In other words, the sheet resistances of the films are equivalent in the region, regardless of which CNT samples are used or whether the CNT films are prepared according to the preparing method of the present application. It is suggested that the discontinuity among carbon nanotubes in the CNT films is the main reason for the convergence of the high resistances. FIG. 3a shows an SEM image of an H-CNT film with 98.8% transparency. It can be seen that these CNTs or CNT bundles are isolated from one another and, therefore, do not form a conducting channel. The whole film is just like an open circuit. Previous theoretical and experimental results have confirmed the effect. See, (a) Snow, E. S. et al., Appl. Phys. Lett. 2003, 82, 2145; and (b) Kumar, S. et al., Phys. Rev. Lett. 2005, 95, 066802. Therefore, the film reaches an exceedingly high sheet resistance of 1.33×10⁵ Ω/sq. Although nanotubes respectively form continuous webs for the P-CNT film (95.3% transparency) and the L-CNT film (95.9% transparency) in FIGS. 3B and 3C, wide uncovered regions on the substrate can be observed. However, due to the formation of a “closed circuit”, their resistances are dramatically decreased. When the transparency of L-CNT film drops to 91%, its sheet resistance is dramatically reduced by 424 Ω/sq. In FIG. 3D, it can be seen that a relatively dense network of interconnected tubes represents multiple conducting channels, which lead to the high conductivity. As discussed in further detail below, such behavior is characteristic of a percolating network. See, (a) Bekyarova, E. et al., J. Am. Chem. Soc. 2005, 127, 5990; (b) Zhou, Y. X. et al., Appl. Phys. Lett. 2006, 88, 123109; and (c) Artukovic, E. et al., Nano Lett. 2005, 5, 757.

During the removal of surfactants and the filter membrane, the MCE filter membrane can be removed much more quickly and completely by using a vapor, compared to the immersion method. For the resistances induced by the Triton X-100, two steps were adopted to extract them. Because Triton X-100 is adsorbed to CNT surfaces in a stable fashion (Wang, H. et al., Nano lett. 2004, 4, 1789; Zhang, Z. B. et al., J. Am. Chem. Soc. 2007, 129, 666), it is difficult to completely wash away Triton X-100 with purified water. Therefore, the Triton X-100 on one side of the SWTN film was removed by a Tris-HCl buffer. Once the CNT film is transferred onto the glass, Triton X-100 is on the reverse side. 50% (v/v) aqueous methanol solution is used to effectively remove the residual Triton X-100 on the reverse side.

### Example 2

In order to examine the existence of the resistances mentioned above, a CNT film on MCE was, on average, divided into four parts, and one part was treated according to the method of prior art, that is, its filter membrane was immersed in acetone for 48 h. The acetone was renewed every 12 h. The resistance of an as-obtained film is taken as a basis (total resistance). The other three parts were treated as follows: removal of the filter membrane with the vapor generator, followed by, respectively, the removal of the Triton X-100 on one side of the film only; the removal of the Triton X-100 on the reverse side of the film only; and the removal of the Triton X-100 from both sides (as an essential CNT film). The results indicate that the resistance of the essential CNT film with 78% transparency accounts for 46% of the total resistance (the inset in FIG. 4). Moreover, FIG. 4 shows the essential CNT film dependence of the transparency. The percent of the essential CNT film rises from 38% to 92% with the increase of transparency from 62% to 96%.

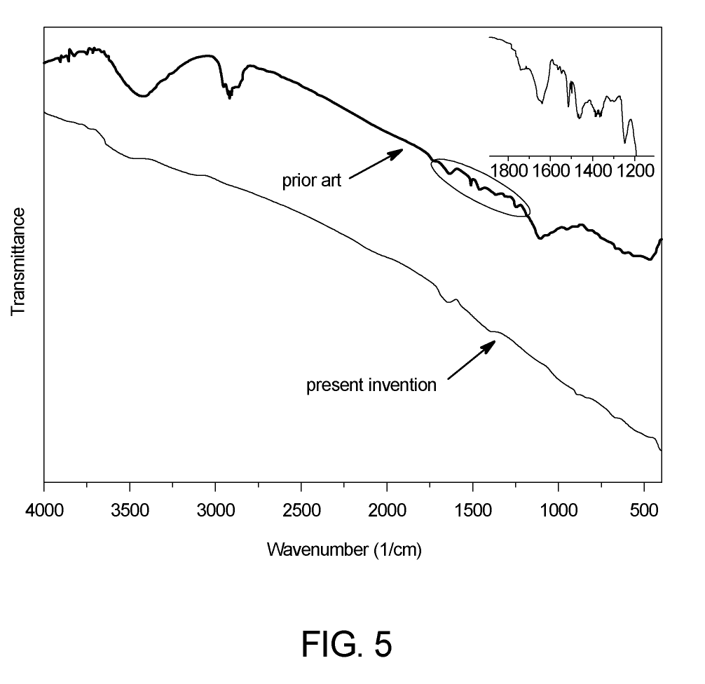

The reason for the change can be understood as follows. If the thickness of the film is decreased (i.e. the transparency is increased), the Triton X-100 on the nanotubes—in particular, on the tube in the center of the bundle—will gradually disappear. At the same time, the filter membrane can also be washed out to a greater extent because of the much smaller contact between the CNT film and the filter membrane. To test the effectiveness of this method, the FT-IR spectra of CNT film prepared according to the prior art preparing method and the preparing method of the present application were compared. From FIG. 5, it can be seen that, in the films prepared according to the prior art preparing method, the characteristic peaks of the Triton X-100 appeared in the spectrum such as C—H (around 2910 cm⁻¹), O—H (around 3430 cm⁻¹), —C(CH₃)₃ (around in 1550 to 1200 cm⁻¹ region) and aromatic ring vibrations (around 1340 and 820 cm⁻¹). However, in the films prepared according to the preparing method of the present application, these characteristic peaks disappear or weaken. The residual peaks should be attributed to the —OH and —COOH groups on the CNTs themselves. Thereby, it is confirmed that the Triton X-100 has been totally removed.

Present example proves that the conduction of the resulting CNT film can be significant improved by the removal of surfactant on both sides of CNT film with respect to the removal of the surfactant on the one side of CNT film. It can be seen from FIG. 4, as mentioned above, when the resistance after the removal of the filter membrane and surfactants according the prior art method is taken as a basis (total resistance), the resistance generated from the surfactants on the reverse side of the CNT film amounts to 26% of the total resistance, and the resistance generated from the surfactants on the opposite side of the CNT film amounts 20% of the total resistance. It is apparent that the further removal of the surfactants on the reverse side of the CNT film after the removal of the surfactants on the opposite side of the CNT film will improve substantially the conductivity of CNT films.

### Example 3

As for the conductivity of the transparent CNT films, they are characterized by a sharp jump of several orders of magnitude, which is attributed to the typical electrical percolation phenomena dealing with network formation of conductive particles in terms of the percolation theory. See, (a) Pike, G. E. et al., phys. Rev. B 1974, 10, 1421; (b) Balberg, I. et al., Phys. Rev. Lett. 1984, 52, 1465; and (c) Vigolo, B. et al., Science 2005, 309, 920.

Percolation is a statistical geometric theory which has established the universality of the exponents in the power law dependence of geometrical parameters. The percolation behavior of CNT network has been reported by many research groups (see, (a) Hu, L.; et al., Nano lett. 2004, 4, 2513 and (b) Unalan, H. E. et al., Nano lett. 2006, 6, 677). In plain terms, for CNT films just above the percolation threshold, sheet resistance reduces dramatically with the increase in the thickness of film, while in the region far from the threshold, sheet resistance decreases inversely with the thickness of the film, as expected for constant conductivity. Near the percolation threshold (p_{c}), the conductivity (σ) is related to the concentration of conducting channels (p) by a universal power law of the form σ∝(p−p_{c})^{α} (see, (a) Stauffer, D.; Introduction to Percolation Theory, Taylor & Francis: London and Philadelphia, 1985. (b) Sahimi, M. Applications of Percolation Theory, Taylor & Francis: London, 1994). The critical exponent, α, provides an index of the system dimensionality, and the theoretical values of 1.3 and 1.94 have been predicted for ideal 2D and 3D systems, respectively. On the other hand, Dettlaff-Weglikowska et al. reported that treatment by thionyl chloride (SOCl₂) offers a simple way to significantly improve the electrical conductivity of a CNT network (see, Dettlaff-Weglikowska, U. et al., J. Am. Chem. Soc. 2005, 127, 5125). They interpreted that SOCl₂-induced conductivity was enhanced by the formation of the CNT/SOCl₂ charge-transfer complexes within the intercalated ropes, which consequently improved the alignment of the nanotube network.

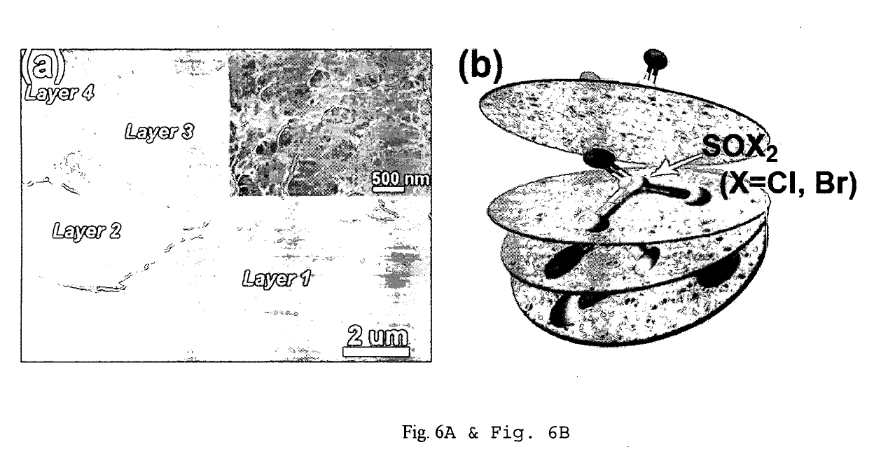

Combining the percolation theory and the chemical modification method for the CNT films, a novel CNT film laminate with a sandwich structure was proposed. In contrast to the case of SOCl₂, a relatively much larger molecule: thionyl bromide (SOBr₂) was used as a dopant. P-Type doping associated with Br₂ intercalation of an CNT bundle has been observed to increase the conductivity significantly (see: (a) Rao, A. M. et al., Nature 1997, 388, 257; (b) Chen, G. et al., Phys. Rev. Lett. 2003, 90, 257403; and (c) Chen, G. et al., Phys. Rev. B 2005, 71, 045408). Moreover, it has been demonstrated by experiments and DFT calculations that there is an interaction between Br and CNTs, and the binding energies of a metallic nanotube and Br are larger than that of a semiconducting nanotube and Br (see, Chen, Z. H. et al., Nano Lett. 2003, 3, 1245). In consequence, in order to increase the critical exponent, a 3-D sandwich structure with four layers was constructed, as shown in FIG. 6. It can be seen that the adhesion between layers is sufficiently strong because of the van der Waals interactions.

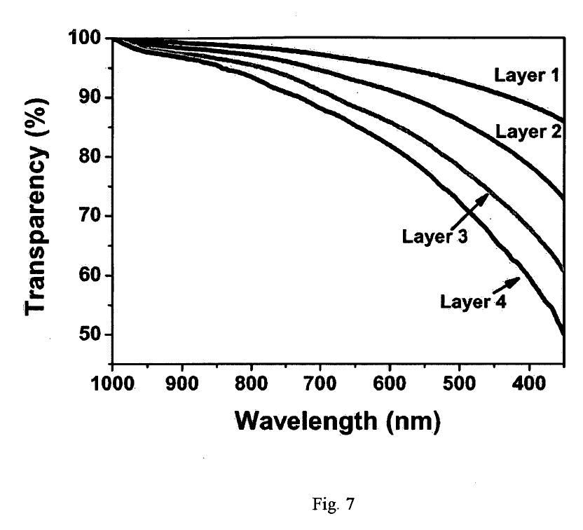

On average, 100 ml of a stable L-CNTs/Triton-X100 solution was divided into four parts, which can provide four uniform CNT films. Each film was then evenly partitioned into four parts. Two of them are for comparing SOCl₂ and SOBr₂ treatments, respectively. The two others are for measuring the transparency and sheet resistance of the pristine CNT film, respectively. After fabricating the CNT films by the preparing method of the first embodiment, two films were immersed into SOCl₂ and SOBr₂ for 6 h, respectively. The process was repeated for layer 2, layer 3 and layer 4. The change in transparency for each different layer is shown in FIG. 7. At 550 nm, the transparency drops from 94.1% to 77.6%. However, when a film was directly prepared using the 100 ml of CNT solution, its transparency is 82.4%. The discrepancy may result from the introduction of dust during the whole fabrication and measurement process. In Table 1, the sheet resistances of the four-layer CNT film laminate were compared by different treatments.

It can be seen that a remarkable change can be provided when using the sandwich structure with charge-transfer complexes. It was found that, under the same transparency, the sheet resistance of the film with a multilayer structure is inferior to that of a monolayer film. However, after each layer of the CNT film was modified, their sheet resistances dropped markedly. The use of SOBr₂ obtains a lower sheet resistance compared with its counterpart SOCl₂. Typically, the sheet resistance of ITO with 80% transparency is less than 100 Ω/sq on glass and 100 Ω/sq to 300 Ω/sq on polyethylene terephalate (PET). Hence, the CNT films of the present application may serve as a replacement for ITO in optoelectronic applications.

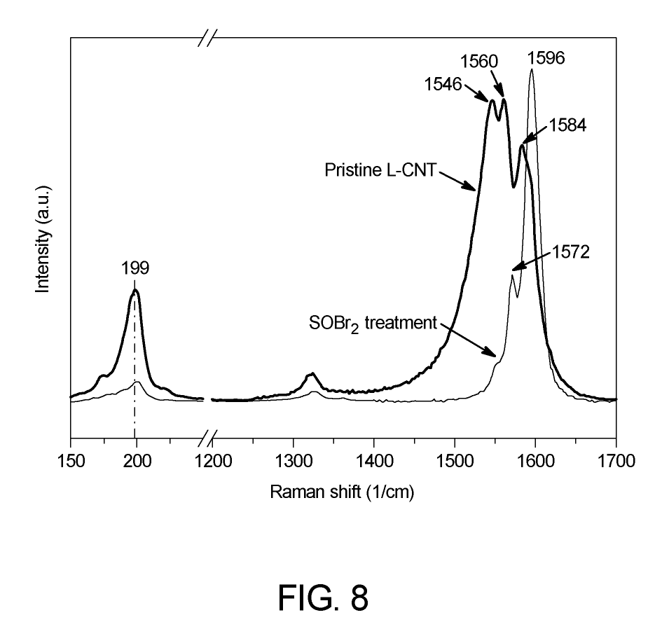

To further explore the electronic transport properties and the mechanism of conduction in the CNT films modified by SOBr₂, Raman spectra before and after the modification were analyzed. In FIG. 8, it can be seen that radial breathing modes (RBM) in ˜199 cm⁻¹ were not greatly affected by the treatment, although the peak intensity decreased to a certain extent. However, there is a dramatic change for the tangential G-band in the region of ˜1500 cm⁻¹ to 1600 cm⁻¹. Removing an electron from a CNT (i.e. p-doping or oxidizing) has been shown to result in an upshift in the G-band peak (see, Dettlaff-Weglikowska, U. et al., J. Am. Chem. Soc. 2005, 127, 5125), as observed here. This conclusion is consistent with extensive observations of the chemical charge-transfer reaction in graphite (see, Eklund, P. C et al., Phys. Rev. B 1992, 20, 5157), C₆₀ (see, Zhou, P. et al., Phys. Rev. B 1992, 46, 2595), and in CNTs (see, Dresselhaus, M. S. et al., Phys Rep. 2005, 409, 47 and also see, (a) Stauffer, D.; Introduction to Percolation Theory, Taylor & Francis: London and Philadelphia, 1985; and (b) Sahimi, M. Applications of Percolation Theory, Taylor & Francis: London, 1994). An upshift of the G-band after refluxing CNT samples in HNO₃ has been observed by several groups (see, (a) Furtado, C. A. et al., J. Am. Chem. Soc. 2004, 126, 6095. (b) Kukovecz, A. et al., J. Phys. Chem. B 2002, 106, 6374). They identified the upshift of the G-band with electron transfer from the nanotube bundle to form NO₃⁻ anions. This interpretation is consistent with work in graphite intercalation compounds (see, Sumanasekera, G. U. et al., J. Phys. Chem. B 1999, 103, 4292). For the case of SOBr₂, the G-band upshift is probably associated with Br anion chemically bonded to the tube walls. This proposal is consistent with the XPS results.

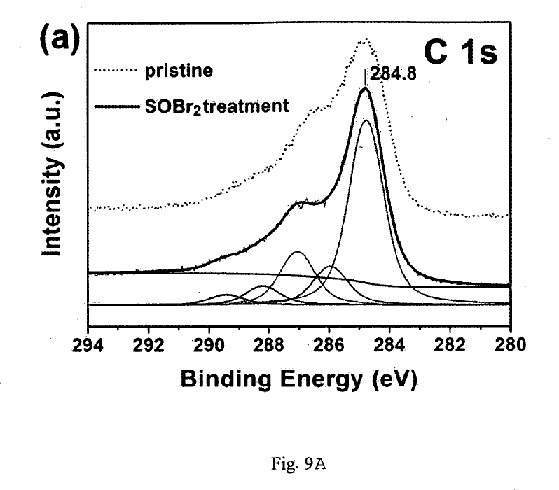

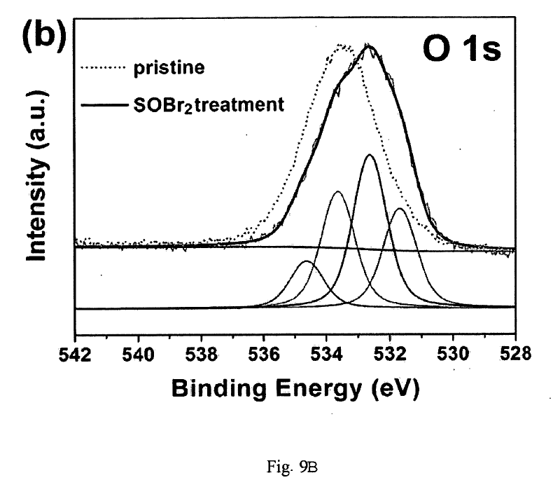

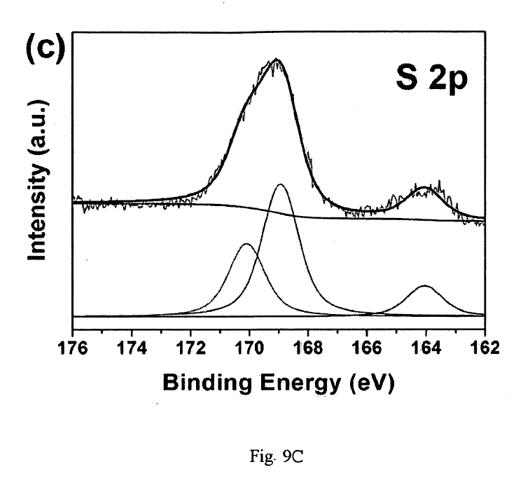

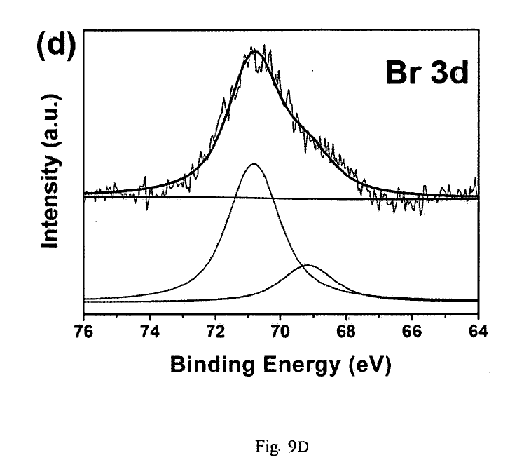

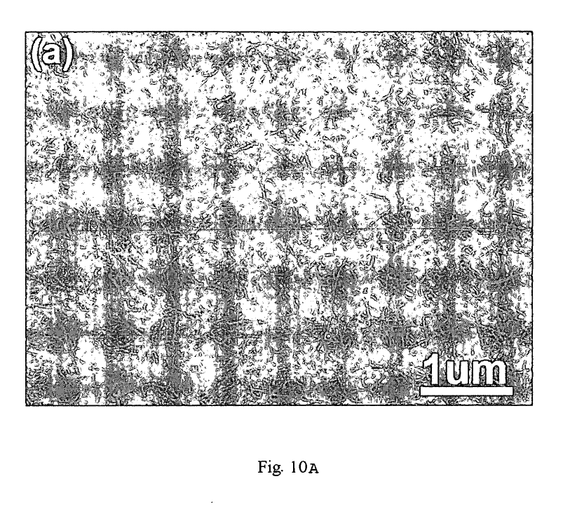

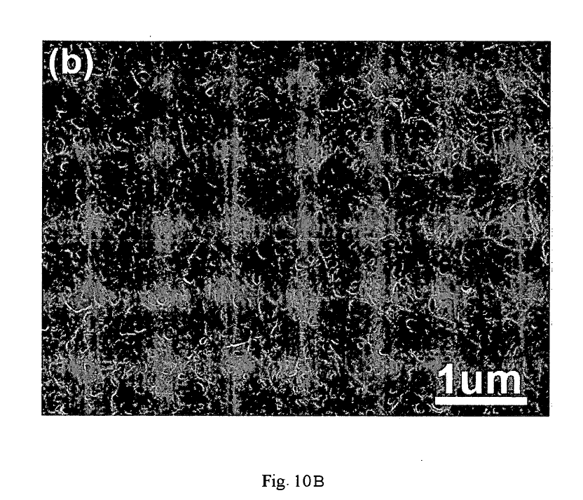

To better understand the surface state of the CNT film, XPS analyses were performed to provide additional information regarding the chemical modification. The resulting XPS C1s core spectra are shown in FIG. 9A, where both samples exhibit a large peak around 284.8 eV, which can be attributed to the sp² carbon atoms of the carbon skeleton. The SOBr₂ treated peak in the C1s spectrum has been fitted to several symmetrical components according to the peak assignment used by Hiura (see, Hiura, H. et al., Adv. Mater. 1995, 7, 275.). The peak at 186.1 eV arises from C—S (see, Ruangchuay, L. et al., Appl. Surf. Sci. 2002, 199, 128), which is coincident with S is spectrum explained later. As indicated in the following documents: Kovtyukhova, N. I. et al. J. Am. Chem. Soc. 2003, 125, 9761; Lee, W. H. et al., Appl. Surf. Sci. 2001, 181, 121; and Ago, H. et al., J. Phys. Chem. B 1999, 103, 8116, the three peaks in the shoulder of the main peak with higher binding energies located at 287, 288.4, and 289.3 eV, can be assigned to C—O (e.g., alcohol, ether), C═O (ketone, aldehyde), COO— (carboxylic acid, ester) species, respectively. These groups should be introduced during the oxidated purification of as-synthesized carbon nanotubes. From 0 is core level XPS spectra in FIG. 9B, an apparent chemical shift after SOBr₂ treatment is seen. It is suggested that the chemical shift may result from the synergistic effect that the amount of oxygen bound with carbon decreases and the amount of oxygen bound with sulfur increases. Dettlaff-Weglikowska (see, Dettlaff-Weglikowska, U. et al., J. Am. Chem. Soc. 2005, 127, 5125) reported that the sulfur S 2p core level exhibits only a single species with the S 2p 3/2 line situated at a binding energy of 168.4 eV. Assignment of this binding energy to SO₄⁻² is based on the S 2p binding energy (168.8 eV) in sodium dodecyl sulfate binding energy. The peak around 169 eV in the present application can also be attributed to the S with the oxidation states of VI (FIG. 9C) (see, Wahlqvist, M. et al., J. Electron. Spectrosc. Relat. Phenom. 2007, 156-158, 310-314), although some variation in position, depending on the compensation results of the charge transfer and screening effect in the SO covalent bond. However, an additional peak occurs at 164.1 eV in the case, which is identical to that of an organic C—S bond (see, (a) Nakamura, T. et al., Diamond Relat. Mater. 2007, 16, 1091; (b) Cavalleri, O. et al., J. Phys.: Condens. Matter 2004, 16, S2477), indicating a —C—S—C— bond may exist in CNTs in covalent bond (see, Wu, Y. P. et al., J. Power Sources 2002, 108, 245.). The possibility of covalent crosslinking between carbon nanotubes has been demonstrated by theoretical calculations and experimental observations (see, (a) Curran, S. A. et al., J. Mater. Res. 2006, 21, 1071. (b) Sudalai, A. et al., Org. Lett. 2000, 2, 3213; (c) Vasiliev, I. et al., J. Appl. Phys. 2007, 102, 024317). Moreover, in FIG. 10, it can be seen that the reinforcement of CNT bundles from SEM images of the CNT films after the chemical modification. Kis, A. et al. have ascertained that the crosslinking between nanotubes can be formed by using moderate electron-beam irradiation, which would bring their application closer to reality (see, Kis, A. et al., Nature Mater. 2004, 3, 153). Analysis of the Br 3d spectra is provided in FIG. 9D. It shows that there are two possible types of C—Br bonds in the modified CNT films, namely charge transfer complexes and covalent bonds. The more intense Br 3d component with a core-level binding energy of 70.8 eV is typical of C—Br covalent bonds. The less intense component with a lower binding energy of 69.1 eV can be assigned to ionic bromine, which bonds much more easily to metallic CNTs in contrast to its semiconducting counterpart (see, Chen, Z. H. et al., Nano Lett. 2003, 3, 1245.). During the process, the oxidation of Br may occur (see, Silvester, D. S. et al., Analyst 2007, 132, 196), which will provide the driving force for charge transfer. The binding state of Br is basically consistent with that of Cl.

According to the theory simulations reported by Behnam, A. and Ural, A. (see, Behnam, A. et al., Phys. Rev. B 2007, 75, 125432), increasing the ratio (Rᵣₐₜᵢₒ) of the tube-tube junction contact resistance (R_{JCT}) to the theoretical contact resistance at the ballistic limit (R₀) results in a large value of the critical exponent α. When Rᵣₐₜᵢₒ is very high, the film resistivity mainly depends on the number of contacts in the conduction paths. As for the 3-D CNT films with the sandwich structure, both the layer-by-layer cumulation and the chemical modification can promote an increase in the number of contacts in the conduction paths. Therefore, there is a dramatically decline when the films are constructed with two layers. However, as cumulation continues, the change in the sheet resistances of the CNT film is not marked. The rate of change of resistivity decreases at high-density values, since adding more nanotubes to an already dense film is less likely to introduce a significant number of new conduction paths or reduce the length and the number of junctions in existing paths.

TABLE 1
Sheet resistances of different layers before and after
the chemical modification.

| | Pristine (Ω/sq) | SOCl₂ (Ω/sq) | SOBr₂ (Ω/sq) |
|---|---|---|---|
| Layer 1 | 5.04 × 10³ | 4.23 × 10³ | 4.02 × 10³ |
| Layer 2 | 456 | 322 | 298 |
| Layer 3 | 303 | 187 | 168 |
| Layer 4 | 184 | 76 | 56 |

### CONCLUSIONS

According to the preparing methods of the present application that utilize a vapor, the residual surfactants and filter membrane in CNT films can be removed without damaging them. After disposing of the appendages, the sheet resistances of the CNT films markedly decrease. Comparing the results for thin films produced by three kinds of CNTs shows that the conducting capability of the L-CNT films is the strongest, while that of the H-CNT films is relatively inferior. It is suggested that the diameter and length of the CNTs are responsible for the differences. Moreover, in combination with the chemical modification method, the CNT film laminate with a sandwich structure were fabricated in order to further improve the conductivity of the thin films. Based on the analytical characterizations, it has been found that CNT films modified by SOBr₂ are superior to their counterparts modified by SOCl₂ due to the formation of the new conduction paths via S atoms between the tubes. Current research is identifying properties to circumvent applications of the transparent conducting CNT films. As a result, they will represent promising thin film materials for macroelectronics and other systems.

It should be appreciated that the methods of the present application are not limited to the specific procedures described herein, and, thus any suitable additional procedures may be utilized. For example, the additional procedures may be suitable conventional procedures, and may include drying, washing and the like.

The term “optional” as used herein means that the subsequently described event or circumstance (such as treatment step) may or may not occur, and that the description includes instances where the event occurs and instances where it does not.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A method for preparing a flexible transparent conducting carbon nanotube film, the method comprising:
dispersing a CNT in a surfactant to form a dispersion;
filtering out the dispersion with a filter membrane and forming a CNT film on the filter membrane; and
removing substantially all of the surfactants on an obverse side of the CNT film by a buffer.

2. The method of claim 1, which further includes removing the filter membrane by using a vapor.

3. The method of claim 1, which further includes removing the surfactant on a reverse side of the CNT film.

4. The method of claim 3, which further includes washing the CNT film and transferring the film onto a substrate before removing the filter membrane and before removing the surfactant on the reverse side.

5. The method of claim 1, wherein the buffer is Tris(hydroxymethyl) aminomethane hydrochloride (Tris-HCl) buffer.

6. The method of claim 1, wherein the filter membrane is a mixed cellulose ester (MCE) filter membrane.

7. The method of claim 1, wherein the surfactant is octyl-phenol-ethoxylate.

8. The method of claim 4, wherein the substrate is quartz substrate.

9. The method of claim 3, wherein the CNT film is immersed in aqueous methanol solution to remove the surfactant on the reverse side of CNT film.

10. The method of claim 2, wherein the vapor is acetone vapor.

11. The method of claim 1, wherein the CNT is SWNT.

12. A method for preparing a flexible transparent conducting carbon nanotube film, the method comprising:
dispersing a CNT in a surfactant to form a dispersion;
filtering out the dispersion with a filter membrane and forming a CNT film on the filter membrane; and
removing the surfactant on an obverse side and a reverse side of CNT film.

13. The method of claim 12, wherein substantially all of the surfactants are removed on the obverse side of the CNT film by a buffer.

14. The method of claim 13, wherein the buffer is Tris(hydroxymethyl)aminomethane hydrochloride (Tris-HCl) buffer.

15. The method of claim 12, wherein the CNT film is immersed in aqueous methanol solution to remove the surfactant on the reverse side of CNT film.

16. The method of claim 12, further comprising transferring the films onto a substrate before removing the surfactant on the reverse side of CNT film.

17. The method of claim 12, wherein CNT is SWNT.

18. A method for preparing a flexible transparent conducting carbon nanotube film, the method comprising:
dispersing a CNT in a surfactant to form a dispersion;
filtering out the dispersion with a filter membrane and forming a CNT film on the filter membrane; and
removing the filter membrane by using a vapor.

19. The method of claim 18, wherein the vapor is an acetone vapor.

20. The method of claim 18, wherein the CNT is SWNT.

21. A CNT material comprising a CNT film prepared by:
dispersing a CNT in a surfactant to form a dispersion;
filtering out the dispersion with a filter membrane and forming a CNT film on the filter membrane; and
removing substantially all of the surfactants on an obverse side of the CNT film by a buffer.

22. A CNT material comprising a CNT film prepared by:
dispersing a CNT in a surfactant to form a dispersion;
filtering out the dispersion with a filter membrane and forming a CNT film on the filter membrane; and
removing the surfactant on an obverse side and a reverse side of the CNT film.

23. A CNT material comprising a CNT film prepared by:
dispersing a CNT in a surfactant to form a dispersion;
filtering out the dispersion with a filter membrane and forming a CNT film on the filter membrane; and
removing the filter membrane by using a vapor.

24. A method of treating a CNT film comprising preparing the CNT film from a CNT, and treating the CNT film with thionyl bromide (SOBr₂) used as a dopant.

25. The method of claim 24, wherein the CNT is SWNT.

26. A CNT film laminate comprising a sandwich structure including a plurality of layers of a CNT film composed of a CNT.

27. The CNT film laminate of claim 26, wherein each layer of the CNT film laminate is treated with thionyl bromide (SOBr₂) used as a dopant.

28. The CNT film laminate of claim 26, wherein the CNT film laminate has a four layer structure.

29. The CNT film laminate of claim 26, wherein the CNT is SWNT.

30. A transparent, flexible anode comprising a CNT film laminate with a sandwich structure including a plurality of layers of a CNT film.

31. An organic light-emitting diode comprising a transparent, flexible anode including a CNT film laminate with a sandwich structure that includes a plurality of layers of a CNT film.

32. A CNT device comprising a CNT film prepared by:
dispersing a CNT in a surfactant to form a dispersion;
filtering out the dispersion with a filter membrane and forming the CNT film on the filter membrane; and
removing substantially all of the surfactants on an obverse side of the CNT film by a buffer.

33. The CNT Device of claim 32, wherein the CNT device is selected from the group consisting of CNT conductive film, field emission source, transistor, conductive wire, spin conduction device, nano-electro-mechanic system (NMES), nano cantilever, quantum computing device, lighting emitting diode, solar cell, surface-conduction electron-emitter display, filter, drug delivery system, space elevator, thermal conductive material, nano nozzle, energy storage system, fuel cell, sensor, and catalyst support material.

34. A CNT device comprising a CNT film prepared by:
dispersing a CNT in a surfactant to form a dispersion;
filtering out the dispersion with a filter membrane and forming the CNT film on the filter membrane; and
removing the surfactant on an obverse side and a reverse side of the CNT film.

35. The CNT device according to claim 34, wherein the CNT device is selected from the group consisting of CNT conductive film, field emission source, transistor, conductive wire, spin conduction device, nano-electro-mechanic system (NMES), nano cantilever, quantum computing device, lighting emitting diode, solar cell, surface-conduction electron-emitter display, filter, drug delivery system, space elevator, thermal conductive material, nano nozzle, energy storage system, fuel cell, sensor, and catalyst support material.

36. A CNT device comprising a CNT film prepared by:
dispersing a CNT in a surfactant to form a dispersion;
filtering out the dispersion with a filter membrane and forming the CNT film on the filter membrane; and
removing the filter membrane by using a vapor.

37. The CNT device according to claim 36, wherein the CNT device is selected from the group consisting of CNT conductive film, field emission source, transistor, conductive wire, spin conduction device, nano-electro-mechanic system (NMES), nano cantilever, quantum computing device, lighting emitting diode, solar cell, surface-conduction electron-emitter display, filter, drug delivery system, space elevator, thermal conductive material, nano nozzle, energy storage system, fuel cell, sensor, and catalyst support material.

38. A CNT device comprising a CNT film that is treated with thionyl bromide (SOBr₂) used as a dopant.

39. The CNT device according to claim 38, wherein the CNT device is selected from the group consisting of CNT conductive film, field emission source, transistor, conductive wire, spin conduction device, nano-electro-mechanic system (NMES), nano cantilever, quantum computing device, lighting emitting diode, solar cell, surface-conduction electron-emitter display, filter, drug delivery system, space elevator, thermal conductive material, nano nozzle, energy storage system, fuel cell, sensor, and catalyst support material.

40. A CNT device comprising a CNT film laminate with a sandwich structure that includes a plurality of layers of a CNT film.

41. The CNT device of claim 40, wherein the CNT device is selected from the group consisting of CNT conductive film, field emission source, transistor, conductive wire, spin conduction device, nano-electro-mechanic system (NMES), nano cantilever, quantum computing device, lighting emitting diode, solar cell, surface-conduction electron-emitter display, filter, drug delivery system, space elevator, thermal conductive material, nano nozzle, energy storage system, fuel cell, sensor, and catalyst support material.
